(19) United States
(12) Patent Application Publication
(10) Pub. No.: US 2026/0342168 A1
(43) Pub. Date: Oct. 29, 2026

(54) PORTABLE ELECTRICAL DEVICE COVER SYSTEM OF ATTACHMENT

(71) Applicant: GenTent Safety Canopies LLC, Nottingham, NH (US)

(72) Inventors: Mark A. Carpenter, Nottingham, NH (US); Brian Thomas, Nottingham, NH (US); Anthony M. Sandoval, East Kingston, NH (US); Timothy Michael Malette, Barrington, NH (US); Mauricio Adrian Villalobos Casares, Merida (MX); Gerry Daniel Guzman Sandoval, Merida (MX)

(21) Appl. No.: 19/189,853

(22) Filed: Apr. 25, 2025

(51) Int. Cl. H02K 5/10; H02K 5/22; H05K 5/03

(52) U.S. Cl. CPC H02K 5/10; H02K 5/22; H05K 5/03

(57) ABSTRACT

A hinged mount assembly includes a clamp section having first and second clamp arms pivotally connected, an adjustable arm section pivotally coupled to the clamp section, and an attachment section adjustably coupled to the adjustable arm section. The attachment section includes an attachment point for securing a device to the hinged mount assembly. The adjustable arm section may include telescoping first and second tubing sections. A pivot sleeve may be pivotally coupled to the clamp section, with an optional spring biasing the pivot sleeve against the clamp section to provide pivotal resistance. The assembly can be used to attach covers or other devices to equipment such as portable generators.

### FIELD OF INVENTION

The present disclosure relates to a system of attachment, and more particularly to an adjustable cantilever hinged mount for securing protective covers to portable electrical devices of a multitude of differing frame or enclosed case structures.

### BACKGROUND

Portable electrical devices such as engine-generators widely used for providing temporary or emergency power in various settings, including recreational vehicles, outdoor events, construction sites, and residential backup during power outages. These engine-generators typically operate by combusting fossil fuels to produce electricity, which results in the emission of exhaust gases and noise. Due to these emissions, portable engine-generators should be operated outdoors and at a safe distance from occupied structures.

While operating engine-generators outdoors is important for safety, it exposes the equipment to environmental elements such as rain, snow, and other weather-related hazards which can damage the device. To prevent weather damage, portable electrical devices may be placed under coverings such as carports, awnings, or canopies. However, existing coverage structures are not always available and setting up a temporary covering may be cumbersome, inconvenient, result in fire danger, or may not give the required protection.

To solve these issues, specialized covers have been developed which can be attached to a portable electrical device to provide protection while the device is in use. One example of these covers is described in US Patent No. 8,997,769. These specialized covers have the benefit of providing protection with a minimum footprint while providing access for controlling or refueling. Additionally, these specialized covers may allow the device to be moved as necessary with the cover installed.

Typically, in-use portable electric device covers are designed to connect to the tubular frame of the device by encircling a round or square tube frame or by use of threaded fasteners installed in holes drilled into the frame. One example of a cover clamp for connecting to tubular frames can be found in WO-2022221656-A1. However, some portable electric devices lack the fully exposed tubular frame necessary for attaching in such a manner due to panels and heat shields attached, or in very close proximity, to the frame. Attaching covers by drilling and using threaded fasteners has a number of drawbacks, such as being cumbersome and time consuming to install and remove, not being easily transferable between devices, and possibility of injury or damage. Therefore, there exists a need for a portable electrical device cover attachment system that can be adapted to portable electric device designs that cannot be served by existing solutions.

### SUMMARY

An apparatus and system for attaching a cover to a portable electrical device is provided. In one embodiment, the hinged mount assembly includes a clamp section having first and second clamp arms pivotally connected, an adjustable arm section rotatably coupled to the clamp section, and an attachment section adjustably coupled to the adjustable arm section. The attachment section includes an attachment point for securing a device to the hinged mount assembly.

According to other aspects of the present disclosure, the hinged mount assembly may include one or more of the following features. The adjustable arm section may include telescoping first and second tubing sections. The adjustable arm section may further include a pivot sleeve pivotally coupled to the clamp section and a spring biasing the pivot sleeve against the clamp section to provide pivotal resistance. The assembly may include a yaw plate positioned between the pivot sleeve and the clamp section, wherein the yaw plate or the pivot sleeve may comprise a textured surface for increasing the pivotal resistance. The first tubing section may be secured within the pivot sleeve and may include a series of adjustment holes along its length, and the second tubing section may include a locking button configured to engage with the adjustment holes of the first tubing section to secure the relative positions of the first and second tubing sections. The attachment section may comprise a mounting hole for receiving a tent pole of an equipment cover. The clamp section may further comprise a clamp bolt pivotally connected to the second clamp arm and a thumb nut threadedly engaged with the clamp bolt for adjusting clamping force between the first and second clamp arms. The assembly may include clamp pads attached to inner surfaces of the first and second clamp arms. The clamp pads may have a textured surface for facilitating grip when tightened. The attachment section may comprise a mounting hole for receiving a tent pole of an equipment cover.

According to another aspect of the present disclosure, a portable equipment cover system is provided. The system includes a plurality of hinged mount assemblies, each hinged mount assembly comprising a clamp section having first and second clamp arms pivotally connected, an adjustable arm section pivotally coupled to the clamp section, and an attachment section adjustably coupled to the adjustable arm section. The attachment section includes an attachment point for securing a device to the hinged mount assembly. The system also includes a cover configured to be secured to the attachment sections of the hinged mount assemblies, wherein the clamp section is adapted to attach to a portion of a generator.

The foregoing summary has outlined some features of the apparatus, system, and method of the present disclosure so that those skilled in the pertinent art may better understand the detailed description that follows. Additional features that form the subject of the claims will be described hereinafter. Those skilled in the pertinent art should appreciate that they can readily utilize these features for designing or modifying other structures for carrying out the same purpose of the apparatus, system, and method disclosed herein. Those skilled in the pertinent art should also realize that such equivalent designs or modifications do not depart from the scope of the apparatus, system, and method of the present disclosure.

### BRIEF DESCRIPTION OF FIGURES

These and other features, aspects, and advantages of the present invention will become better understood with regard to the following description, appended claims, and accompanying drawings where:

FIG. 1 illustrates an oblique view of a hinged mount assembly, according to aspects of the present disclosure.

FIG. 2 illustrates another oblique view of the hinged mount assembly of FIG. 1, according to an embodiment.

FIG. 3 illustrates a close-up view of a clamp section, according to aspects of the present disclosure.

FIG. 4 illustrates an orthogonal view of a yaw plate, according to an embodiment.

FIG. 5 illustrates an oblique view of a generator with cover, according to aspects of the present disclosure.

FIG. 6 illustrates a perspective view of a portable generator with a protective cover support structure, according to an embodiment.

FIG. 7 illustrates an alternative embodiment of a hinged mount assembly, according to aspects of the present disclosure.

FIG. 8 illustrates a view of another embodiment of a hinged mount assembly, according to aspects of the present disclosure.

### DETAILED DESCRIPTION

In the Summary above and in this Detailed Description, and the claims below, and in the accompanying drawings, reference is made to particular features, including method steps, of the invention. It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with/or in the context of other particular aspects of the embodiments of the invention, and in the invention generally. The term “comprises” and grammatical equivalents thereof are used herein to mean that other components, ingredients, steps, etc. are optionally present. For example, an article “comprising” components A, B, and C can contain only components A, B, and C, or can contain not only components A, B, and C, but also one or more other components.

The present disclosure relates to a hinged mount assembly and associated system for attaching devices to structures that are typically difficult to attach to using existing devices. Particularly, the clamp assembly allows a strong connection to various sizes of round, square, oval, triangular, and other shaped tubing even in cases where the entire circumference of the tube cannot be encircled. In one specific example, the clamp assembly may be used for securing covers to portable electrical devices such as portable engine-generators.

Depending on the application, a system may comprise one or more hinged mount assemblies. When used to attach a cover to portable equipment, four hinged mount assemblies may be used, though fewer or more may be used depending on the particular application. The hinged mount assemblies may be designed to attach to different portions of the equipment, such as a generator frame or housing. The hinged mount assemblies may include an adjustable arm section to allow optimal positioning of the clamp, thus allowing the hinged mount assemblies to be used on a variety of different devices. In other words, due to the adjustability of the hinged mount assemblies, a single cover system can be utilized on a wide range of different equipment sizes and designs, increasing the usefulness of the cover system while reducing inventory needs compared to non-adjustable systems. The cover is configured to be secured to the hinged mount assemblies, providing protection for the equipment while maintaining portability and accessibility. This adaptability allows the system to be used with different generator models and designs, providing a flexible solution for attaching protective covers.

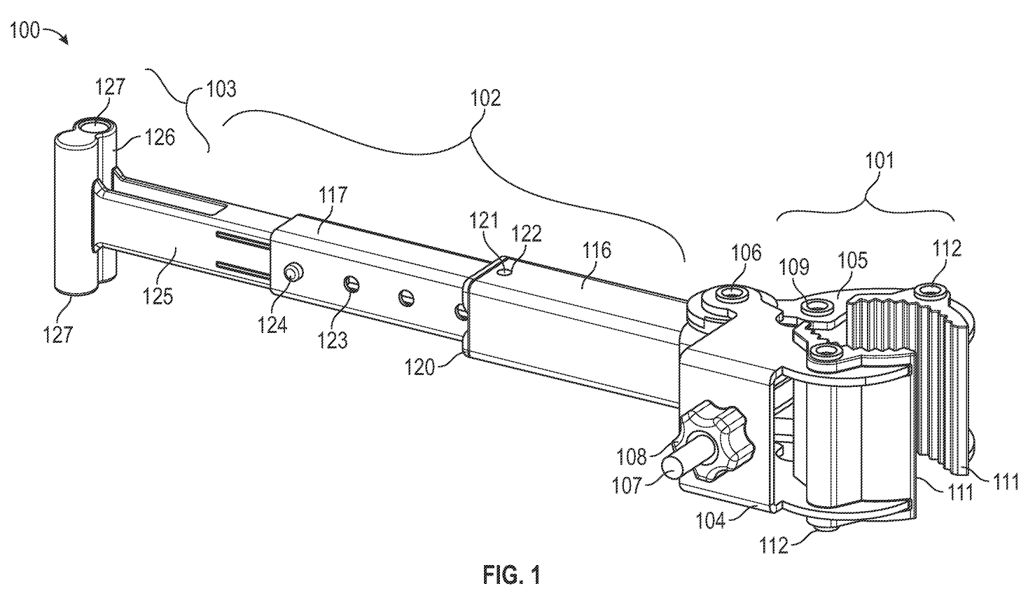

The hinged mount assembly 100 as shown in FIGS. 1-4 comprises three main sections that work together to provide adjustable and secure attachment:
1. Clamp section 101 may include pivotally connected clamp arms for attaching to a structure such as a frame of a portable electrical device.
2. Adjustable arm section 102 may include telescoping tubing sections that allow for length adjustment and pivotal positioning relative to the clamp section.
3. Attachment section 103 may include an attachment point for securing a device to the hinged mount assembly.

These sections may work together to provide a versatile clamping mechanism that can adapt to various structures and securely hold attached devices in adjustable positions. The assembly may allow for multiple points of adjustment through the telescoping sections, pivoting joints, and rotational interfaces while maintaining structural stability.

The hinged mount assembly 100 comprises a clamp section 101 designed to securely attach the assembly to various structures. The clamp section 101 includes a first clamp arm 104 and a second clamp arm 105. The first clamp arm 104 and the second clamp arm 105 may be pivotally connected by a clamp arm rivet 106. In some cases, the first clamp arm 104 and the second clamp arm 105 may be made from flat or bent sections of sheet metal, such as steel, providing strength and durability to the clamp section 101.

To facilitate a clamping force between the first and second clamp arms, a clamp bolt 107 may be pivotally connected to the second clamp arm 105. As shown in FIG. 1, the clamp bolt 107 may be attached to the second clamp arm 105 via a clamp bolt rivet 109. The clamp bolt rivet 109 may pass through holes in the body of the second clamp arm 105 and a hole at one end of the clamp bolt 107. In some cases, spacers 110 may be positioned on either side of the clamp bolt 107 to keep the clamp bolt 107 centered. The clamp bolt 107 may then pass through a hole in the first clamp arm 104.

A thumb nut 108 may be threadedly engaged with the clamp bolt 107. The thumb nut 108 may be used for adjusting clamping force between the first clamp arm 104 and the second clamp arm 105. The thumb nut 108 may have knurling, arms, wings, or other features attached to or formed integrally with the thumb nut 108. This arrangement allows a user to easily tighten or loosen the clamp section 101 as needed.

Other mechanisms for applying force between the first and second clamp arms may be used. Any threaded fastener or member may be used to draw the clamp arms together when there is relative rotation between the threaded member and nut. For example, clamp bolt rivet 109 may be replaced with a barrel nut having a threaded hole passing orthogonally through the nut. A stud, screw, or bolt may then be used in place of clamp bolt 107 which passes through the threaded hole of the barrel nut. The screw may have knurling, arms, wings, or other features attached to or formed integrally with the screw to facilitate hand tightening.

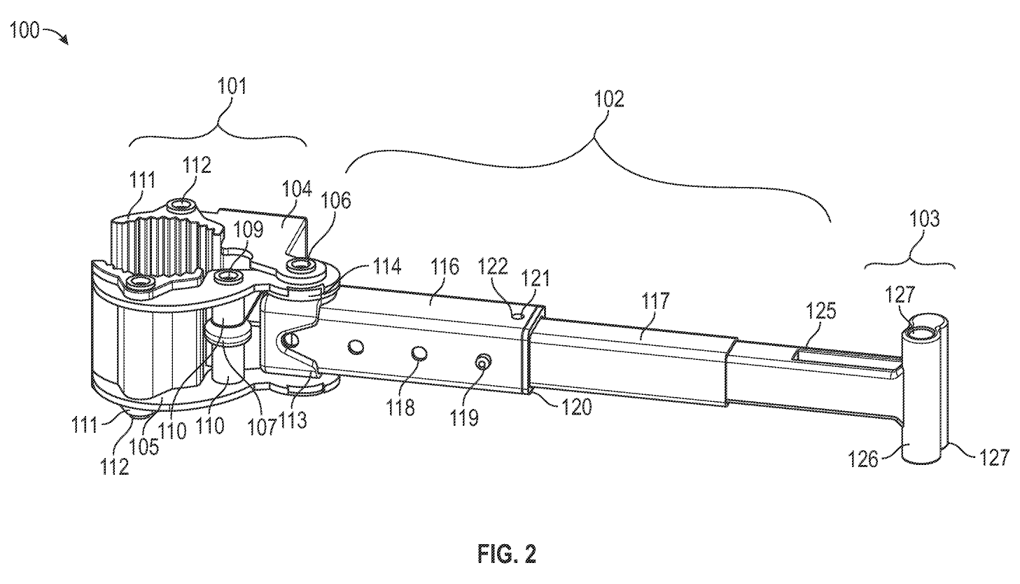

The hinged mount assembly 100 may include clamp pads 111 attached to inner surfaces of the first clamp arm 104 and the second clamp arm 105. As illustrated in FIGS. 1 and 2, the clamp pads 111 may be attached to the clamp arms via clamp pad rivets 112 or by other mechanical fastening methods, adhesives, etc. In some cases, the clamp pads 111 may be made of a material such as rubber to enhance the grip on the structure being clamped.

The clamp pads 111 may have a textured surface for facilitating grip when tightened. In some implementations, the clamp pads 111 may have a ribbed texture. This ribbed texture may provide enhanced grip on round, oval, and rectangular tubular members.

The specific texture and material can be selected based on the intended application, considering factors like expected loads, environmental conditions, and characteristics of the clamped objects. Multiple textures or materials could be used in different zones of the pad to optimize grip on various surface types.

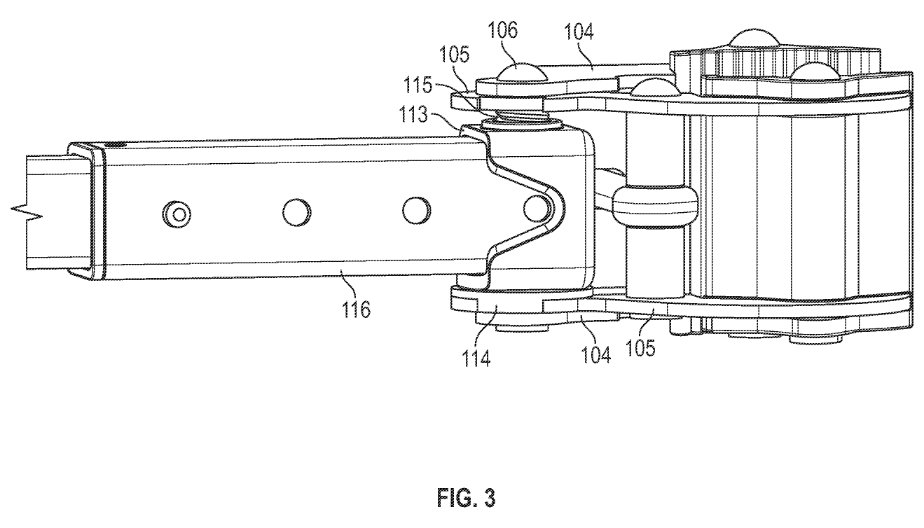

FIG. 3 provides a close-up view of the clamp section 101, further illustrating the pivotal connection between the first clamp arm 104 and the second clamp arm 105 via the clamp arm rivet 106. This pivotal connection allows the clamp arms to open and close, accommodating various sizes and shapes of structures to which the hinged mount assembly 100 may be attached.

To attach the hinged mount assembly 100 to a structure, a user may open the first clamp arm 104 and the second clamp arm 105 by loosening the thumb nut 108. The clamp pads 111 may then be placed onto the structure, and the thumb nut 108 may be tightened, causing the first clamp arm 104 and the second clamp arm 105 to compress the clamp pads 111 against the structure. The thumb nut 108 may be adjusted to apply more or less pressure as desired to facilitate grip.

In order to provide adjustability in attachment, the hinged mount assembly 100 may include an adjustable arm section 102 pivotally coupled to the clamp section 101. The adjustable arm section 102 may comprise a pivot sleeve 113 pivotally coupled to the clamp section 101. In some cases, the pivot sleeve 113 may be connected to the clamp section 101 via the clamp arm rivet 106, allowing the adjustable arm section 102 to pivot around the axis of the clamp arm rivet 106.

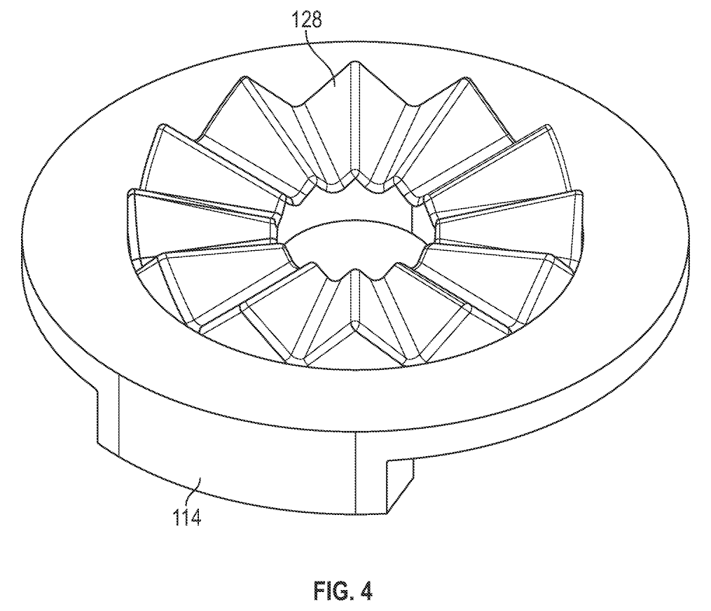

A yaw plate 114 may be positioned between the pivot sleeve 113 and the second clamp arm 105 of the clamp section 101. FIG. 4 provides an orthogonal view of the yaw plate 114, showing a textured surface 128 on the yaw plate 114. The textured surface 128 may comprise a triangular wave surface as shown or sinusoidal wave surface for increasing pivotal resistance through friction or inflection point. In some cases, the pivot sleeve 113 may also have a textured surface which may be complementary to the textured surface 128 of the yaw plate 114.

As shown in FIG. 3, a spring 115 may be positioned between the second clamp arm 105 and the pivot sleeve 113. The spring 115 may bias the pivot sleeve 113 against the clamp section 101 to provide pivotal resistance.

The adjustable arm section 102 may further comprise telescoping first and second tubing sections. As illustrated in FIGS. 1 and 2, a first tubing section 116 may be secured within the pivot sleeve 113 via clamp arm rivet 106. The first tubing section 116 may include a series of adjustment holes 118 along its length.

A second tubing section 117 may be configured to telescopically engage with the first tubing section 116. The second tubing section 117 may include a locking button 119 configured to engage with the adjustment holes 118 of the first tubing section 116. This arrangement allows for securing the relative positions of the first tubing section 116 and the second tubing section 117.

A bushing 120 may be positioned between the first tubing section 116 and the second tubing section 117. In some cases, the bushing 120 may be a plastic component shaped to fit snugly within the first tubing section 116 and provide a desired slip fit with respect to the second tubing section 117. The bushing 120 may include a bushing lock 121 designed to fit within a bushing lock hole 122 in the first tubing section 116 to secure the bushing 120 in the first tubing section 116.

The adjustable arm section 102 may further comprise a rectangular body 125 configured to telescopically engage with the second tubing section 117. A locking button 124 may be included on the rectangular body 125 to secure the attachment section 103 at various positions relative to the second tubing section 117. In some cases, the locking button 124 may be formed as a protrusion on a cantilever arm formed in the rectangular body 125. The cantilever arm may provide flexibility and spring force to allow the locking button 124 to be depressed for adjustment while remaining locked when in place.

The second tubing section 117 may include a series of adjustment holes 123 along its length. The locking button 124 may be configured to engage with the adjustment holes 123, allowing for secure positioning of the attachment section 103 relative to the second tubing section 117.

The first tubing section 116, the second tubing section 117, and the rectangular body 125 may be made of metal, polymer, or other suitable material. In one embodiment, the first tubing section 116 and the second tubing section 117 are comprised of rectangular metal tubular bodies while the rectangular body 125 is comprised of a polymer.

The adjustable arm section 102 may therefore provide multiple points of adjustment through the telescoping tubing sections and pivotal interfaces. This adjustable design provides flexibility in the positioning of the clamp to optimize attachment to a variety of devices. Thus, a single cover system using one or more hinged mount assemblies may be used on a wide variety of portable electrical devices.

The hinged mount assembly 100 may further include an attachment section 103 attached to the adjustable arm section 102. The attachment section 103 may comprise an attachment point 126 attached to or formed integrally with the rectangular body 125. The attachment point 126 may be designed for securing a device to the hinged mount assembly 100. In the embodiment shown, the attachment point 126 is comprised of an overlapping pair of cylinders, each with a blind hole open to opposite ends, referred to as mounting holes 127.

Each mounting hole 127 may be designed for receiving a tent pole of a portable electrical device cover. In some implementations, the mounting hole 127 may be roughly parallel with the clamp pads 111. By having mounting holes 127 on opposing sides, one mounting hole will be accessible regardless of which way the hinged mount assembly 100 is installed.

The design of the attachment section 103 may allow for secure connection to devices such as generator covers. The adjustable nature of the attachment section 103, combined with the adjustability of the other sections of the hinged mount assembly 100, may provide versatility in attaching and positioning various devices.

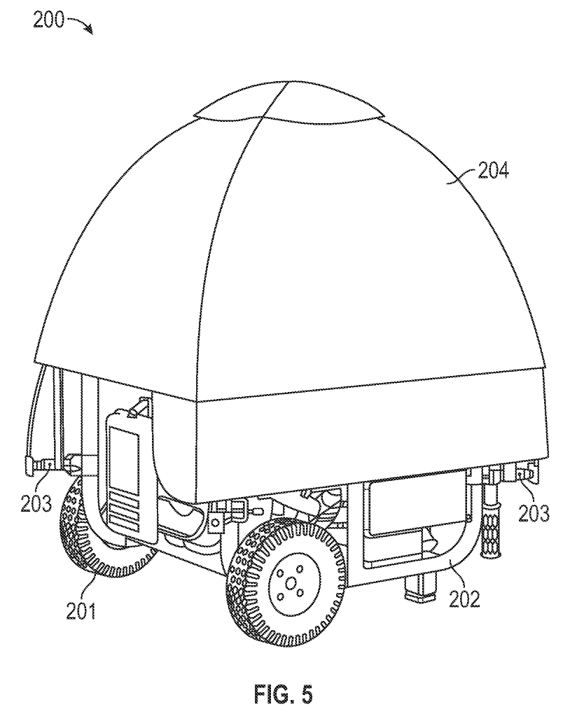

FIG. 5 illustrates an engine-generator with cover 200, which demonstrates the application of the hinged mount assembly in securing a cover to portable electrical equipment. The generator 201 has a support frame 202 in the form of tubular members. The support frame 202 may provide structural support for the generator 201 and serve as mounting points for the hinged mount assemblies 203. The hinged mount assemblies 203 serve as attachment point for the cover 204.

A plurality of hinged mount assemblies 203 may be attached to various points on the support frame 202. The hinged mount assemblies 203 may correspond to the previously described hinged mount assembly 100. To attach each hinged mount assembly 203 to the support frame 202, a user may first loosen the thumb nut of the clamp section. The user may then position the first clamp arm and the second clamp arm onto a suitable portion of the support frame 202. The thumb nut is then tightened to secure the hinged mount assembly 203 in place with the help of the clamp pads.

To secure the cover 204 to the generator 201 using the hinged mount assemblies 203, the user may first adjust the adjustable arm section of each hinged mount assembly 203. This adjustment may involve pivoting the adjustable arm section relative to the clamp section and extending or retracting the first tubing section, the second tubing section, and the rectangular body 125 to achieve the desired position.

The attachment section of each hinged mount assembly 203 may be positioned to align with corresponding attachment points on the cover 204. The user may then insert tent poles or similar support structures of the cover 204 into the mounting holes of the attachment points. The mounting holes may securely hold the tent poles, thereby supporting the cover 204 above the generator 201.

In some cases, the user may need to make fine adjustments to the positioning of the hinged mount assemblies 203 to ensure proper fit and tension of the cover 204. This may involve readjusting the telescoping sections or pivoting the pivot sleeve of the hinged mount assemblies 203.

The cover 204 may be a protective structure designed to shield the generator 201 from environmental elements such as rain, snow, or other hazards. The cover 204 may have a dome-shaped design that extends over the entire generator assembly. In some cases, the cover 204 may be made of a durable, weather-resistant material.

The resulting assembly may provide protection for the generator 201 while maintaining accessibility for operations such as making connections, adjusting controls, adding fuel, or changing oil. The use of multiple hinged mount assemblies 203 may allow for a secure and stable attachment of the cover 204 to the generator 201, even in windy conditions.

The embodiment shown in FIG. 5 is only one example of such an application of a hinged mount assembly. Depending on the particular configuration of the generator and cover, more or less hinged mount assemblies may be used. The hinged mount assemblies may be used in any orientation and attached to any usable location on the device. Additionally, such a hinged mount assembly mechanism may be used for many other purposes such as attaching accessories to portable electric devices or even other structures or equipment. For example, the hinged mount assembly may be used to attach wheels and a handle to portable electric devices for ease of movement or attach a cup holder to a pop-up canopy tent pole.

In various configurations, the hinged mount assembly can be envisioned as having three sections. The first section is a clamp section (e.g., clamp section 101 from FIG. 1) designed to be attached to a structure. The second is an application end which defines the component that the hinged mount assembly is designed to attach to the structure. The application end may be any number of components, such as a tent pole attachment, handle, wheel, cup holder, etc. The third is referred to as the nexus which defines the connection between the clamp and the application end. The nexus may have one or more degrees of freedom for movement, such as pivoting or rotating, or may be fixed. Together, these three sections provide attachment of a device to a structure.

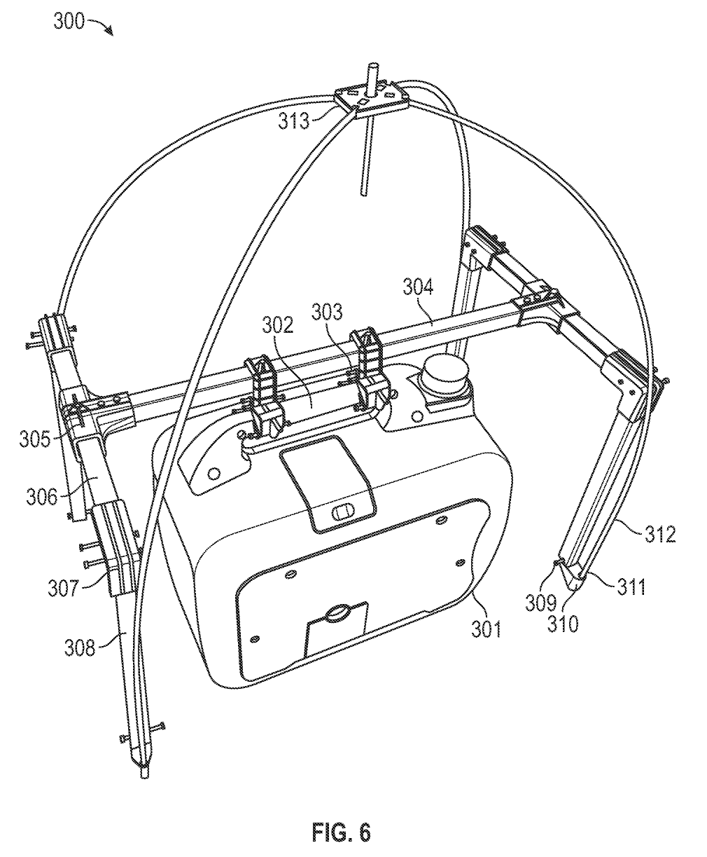

For some equipment/structures, a different attachment system may be utilized. For example, FIG. 6 illustrates an isometric view of a different type of portable engine-generator with a protective cover support structure 300. The generator 301 features a fully enclosed body and a single horizontal handle 302, which is typical of similar generators. Due to this handle configuration, a cover system such as that shown in FIG. 5 may not be suitable.

The protective cover support structure 300 is attached to the handle 302 of the generator 301 via two clamp sections 303. These clamp sections 303 may be similar to those described with respect to FIGS. 1-5. The clamp sections 303 are slidably connected to the main tubular member 304 and may also pivot, rotate, or otherwise be movable to connect to various equipment configurations.

At each end of the main tubular member 304 is a T-shaped connector 305. These T-shaped connectors 305 connect the main tubular member 304 to side tubular members 306, which extend in either direction from the ends of the main tubular member 304.

At the ends of each of the side tubular members 306 is an angle connector 307. These angle connectors 307 are also connected to vertical tubular members 308, which extend downward toward the ground.

At the lower end of each vertical tubular member 308 is a foot 309. The foot 309 is connected to the vertical tubular member 308 and may be designed to contact the ground. In some cases, the foot 309 may have a textured surface or rubber pad on the bottom to enhance stability or prevent slipping.

Each foot 309 comprises an attachment point 310 in the form of a cylindrical hole 311. A tent pole 312 is inserted into each cylindrical hole 311. The four tent poles 312 meet in the center and are connected to a central pole block 313. The central pole block 313 and tent poles 312 provide support for a cover placed thereon.

In this embodiment, the clamp section 303 may be referred to as the portion which is designed to be attached to a structure. Components 304-311 may be referred to as the application end, and the connection between the two may be referred to as the nexus. The nexus may include rotating, pivoting, or otherwise adjustable interfaces between clamp section 303 and main tubular member 304.

The tubular members (304, 306, 308) may be made of polymer or metal such as steel or aluminum and may have a square, round, oval, or any other shape cross-section. The T-shaped connectors 305, angle connectors 307, and feet 309 may be made of a polymer or metal and may be attached using fasteners, adhesives, interference fits, or any other suitable methods.

In operation, the cover may be installed on a piece of equipment using the following method. The clamp sections 303 are adjusted into position to connect to the equipment. The jaws of the clamp sections are opened, placed over a portion of the equipment, and the clamp sections 303 are tightened as desired. The tent poles 312 are attached, such as by inserting the tent poles 312 into cylindrical holes 311 in the feet 309. A cover is installed over the tent poles 312, providing protection for the equipment.

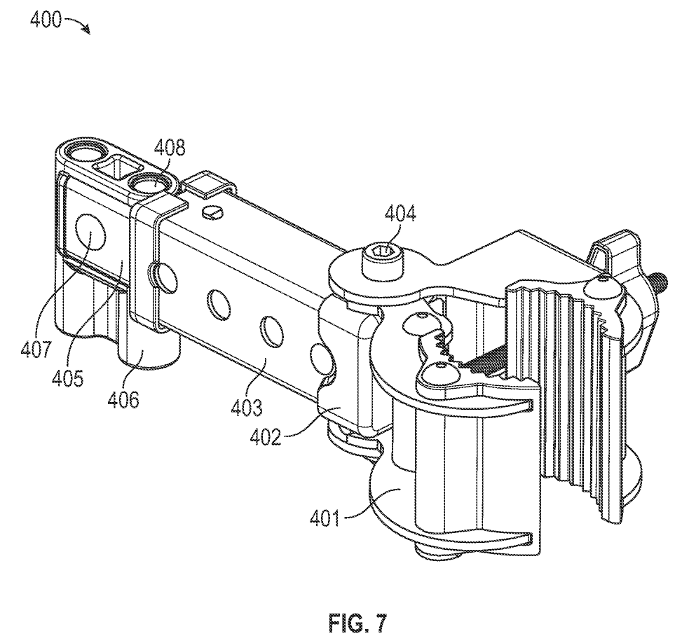

FIG. 7 illustrates an alternative embodiment of a hinged mount assembly 400. The assembly comprises several interconnected components that work together to provide adjustable clamping and mounting capabilities.

The hinged mount assembly 400 includes a clamp section 401 designed to securely attach the assembly to various structures. The clamp section 401 may be pivotally connected to other components of the assembly, allowing for adjustment.

A pivot sleeve 402 is pivotally connected to the clamp section 401. The pivot sleeve 402 may provide support and allow for movement of the assembly relative to the clamped structure.

The assembly includes a first tubing section 403 that is pivotally connected to both the clamp section 401 and the pivot sleeve 402. This connection may be achieved through a threaded fastener 404, which passes through the clamp section 401, pivot sleeve 402, and first tubing section 403, allowing for pivotal movement between these components. By varying the torque applied to the threaded fastener, friction between the clamp section 401 and the pivot sleeve 402 can be modulated to create a desired holding force to hold the first tubing section 403 in a desired position while still allowing adjustability.

A second tubing section 405 is slidably connected to the first tubing section 403. This sliding connection may allow for adjustable positioning when securing the assembly to a structure.

An attachment section 406 is connected to the second tubing section 405. The attachment section 406 may be secured to the second tubing section 405 via a fastener 407. In some implementations, the attachment section 406 may be made of a polymer material and may fit into a corresponding notch in the second tubing section 405 for secure mounting. In some embodiments, the second tubing section 405 can be removed from first tubing section 403, inverted and reinstalled into first tubing section 403 to allow flexible positioning of the clamp section 401.

The attachment section 406 features two attachment points 408. These attachment points 408 may be comprised of cylindrical blind holes which can be used for receiving tent poles or other support structures for a protective cover.

The design of this alternative embodiment may provide additional flexibility in attaching and positioning covers or other accessories on equipment with varying structures. The sliding connection between the first and second tubing sections, combined with the pivotal connections of other components, may allow for a wide range of adjustment to accommodate different mounting scenarios.

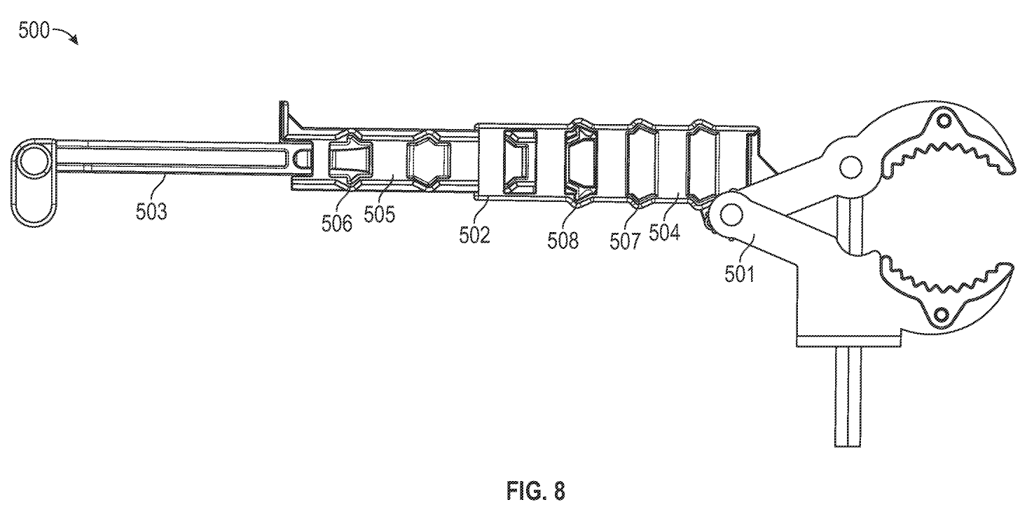

FIG. 8 illustrates an isometric view of a hinged mount assembly 500 according to an embodiment of the present disclosure. The assembly comprises a clamp section 501 connected to an adjustable arm section 502 that terminates in an attachment section 503.

The clamping mechanism 501 may be pivotally connected to the adjustable arm section 502 and may function similarly to the embodiment described with respect to FIGS. 1-4. This pivotal connection may allow for adjustment of the assembly relative to the clamped structure.

The adjustable arm section 502 may consist of two telescoping rectangular tubing sections that allow for length adjustment. The first tubing section 504 may be pivotally connected to the clamp section 501. The second tubing section 505 may slide within the first tubing section 504, providing a means for adjusting the overall length of the assembly.

The attachment section 503 may comprise a rectangular body that telescopically engages with the second tubing section 505. At its end, the attachment section 503 may feature a mounting point with a cylindrical opening for attaching a tent pole or similar support structure.

The attachment section 503 and second tubing section 505 may each comprise a pair of cantilevered prongs 506 which may be biased outwardly. Prongs 506 may be shaped like angled wings that are raked away from the clamping mechanism 501. These prongs 506 may be designed to engage with detents 507 which may be comprised of grooves in the body of the first and second tubing sections.

Detents 507 may be shaped with a double sloping side to cause prongs 506 to move inward upon the application of a sliding force. Prongs 506 may then deform inward as they exit detents 507 and then deform outward at the next detent, providing an easy means of length adjustment. This mechanism may allow for quick and secure positioning of the telescoping sections.

At the end of the telescoping sections, a stop detent 508 may be used to prevent the second tubing section or attachment section from being removed entirely. The stop detent 508 may have a single angled side, thus only allowing the prongs to slide one way out of stop detent 508. This feature may help maintain the integrity of the assembly during use and adjustment.

The design of the first and second tubing sections and the attachment section may allow for a cost-effective injection molding process of manufacture. This manufacturing method may contribute to the overall affordability and durability of the hinged mount assembly.

The hinged mount assembly 500 may provide a versatile and adjustable solution for attaching covers or other accessories to various equipment designs, particularly those lacking conventional frame structures for attachment. The multiple points of adjustment through the telescoping sections and the secure locking mechanisms may allow for precise positioning and stable attachment in a variety of applications.

In addition to covers, a hinged mount assembly as described herein may be used for a number of applications, such as attaching handles, wheels, or auxiliary frames to equipment. Due to the particular design of the clamp section, the clamping force and therefore stability of the clamp may be greatly improved over previous designs.

The various components herein, such as the clamp arms, pivot sleeve, tubing sections, rectangular body, and attachment section may be made of any known material including metals or polymers. Some specific material variations and combinations could include:
Aluminum alloys for lightweight strength in the clamp arms and tubing sections
High-strength steel for the clamp arms to withstand high clamping forces
Titanium alloys for corrosion resistance in marine or chemical environments
Carbon fiber reinforced polymers for high strength-to-weight ratio in the tubing sections
Glass-filled nylon for dimensional stability and wear resistance in the pivot sleeve
Polycarbonate for impact resistance in the attachment section
Thermoplastic elastomers for the clamp pads to provide grip and conformability
Stainless steel for corrosion resistance in outdoor applications
Magnesium alloys for ultra-lightweight components
Ceramic matrix composites for extreme temperature resistance
Shape memory alloys like Nitinol for the clamp arms to provide adjustable clamping force
Hybrid materials combining metal and polymer layers for optimized properties
3D-printed lattice structures using metal powders for weight reduction
Electrically conductive polymers for static dissipation when clamping sensitive electronics

The choice of materials may be optimized based on the specific application requirements, such as weight constraints, environmental conditions, load-bearing capacity, and cost considerations. Multiple materials may be used in different components or even within a single component to achieve the desired performance characteristics.

The connections in the hinged mount assembly could be implemented using various fastening mechanisms instead of rivets, including:
Threaded fasteners such as machine screws or bolts with lock nuts, lock washers, or thread locker
Press-fit pins made of hardened steel or durable polymers
Clevis pins with retaining clips or cotter pins for quick release capability
Interlocking snap-fit features molded directly into polymer components
Axles or shafts with retaining rings or e-clips on the ends
Swaged or cold-formed connections

The choice of pivotal connection method could be selected based on factors like required strength, ease of assembly/disassembly, cost, and suitability for the materials used in the clamp components. Using alternative connection methods may provide benefits in manufacturability, durability, or functionality compared to riveted joints.

The clamp pads may be made of various materials to enhance grip and durability, including:
Synthetic rubbers like neoprene or silicone for weather resistance and flexibility
Thermoplastic elastomers (TPE) for a combination of rubber-like properties and processability or Thermoset elastomers (EPDM) for excellent weather and heat resistance
Polyurethane for high abrasion resistance and load-bearing capacity
Cork-rubber composites for vibration dampening and conformability
Fiber-reinforced polymers for increased strength and stiffness
Micro-textured or micro-patterned surfaces to increase friction coefficient
Dual-durometer materials with a softer gripping layer bonded to a stiffer backing
Self-healing polymers that can repair minor surface damage
Antimicrobial materials to prevent growth of mold or bacteria in damp conditions
Electrically conductive rubbers to dissipate static charge
High-friction coatings applied to a rigid substrate for a thin but effective gripping surface

The clamp pad material may be selected based on the specific application, considering factors like expected loads, environmental conditions, and the surface characteristics of the clamped object. Multiple materials or layered constructions could be used to optimize both grip and durability.

The clamp pads may incorporate various textures and materials to enhance grip and functionality:
Micro-suction pad material that uses tiny suction cups to adhere to smooth surfaces without leaving residue
Dual-durometer construction with a softer gripping layer bonded to a stiffer backing for conformability and strength
Directional grip patterns like angled ridges or scales to resist sliding in one direction
High-friction silicone or thermoplastic elastomer coatings applied to a rigid substrate
Textured metallic inserts embedded in the pad surface for gripping harder materials
Self-cleaning textures with channels to expel debris and maintain grip in dirty environments
Replaceable grip surfaces that can be swapped out for different applications or when worn
Vibration-dampening materials like gel-filled pads to reduce transmitted vibrations
Electrically conductive rubber compounds to dissipate static charge when clamping sensitive electronics

In addition to the locking button described herein, the locking mechanism on the tubing sections may utilize different mechanical designs such as:
A spring-loaded ball detent that engages with holes or depressions in the second tubing section
A friction-based locking mechanism using a cam lever to apply pressure against the inner wall of the second tubing section
A threaded locking collar that tightens around the second tubing section when rotated
A pin-and-hole system where a retractable pin engages with a series of holes along the second tubing section

The locking button could be formed in various ways:
Injection molded as an integral part of the rectangular body using a living hinge design
A separate metal component attached to the rectangular body via rivets or screws
A magnetic locking mechanism using rare earth magnets embedded in both the rectangular body and second tubing section
A ratchet and pawl system allowing easy extension but preventing retraction unless released
An internal expanding collet activated by twisting the attachment section
A series of interlocking teeth on both sections that engage when twisted relative to each other

The locking mechanism could incorporate additional features:
A visual or audible indicator to confirm secure locking
A dual-action release requiring two motions to prevent accidental disengagement
An auto-locking feature that engages when the sections reach certain positions

The implementations set forth in the foregoing description do not represent all implementations consistent with the subject matter described herein but are examples consistent with the disclosed subject matter. Although variations have been described in detail above, other modifications or additions may be possible. In particular, further features and/or variations may be provided in addition to those set forth herein. For example, the implementations described above may be directed to various combinations and subcombinations of the disclosed features and/or combinations and subcombinations of several further features disclosed above. In addition, the logic flow depicted in the accompanying figures and/or described herein do not necessarily require the particular order shown, or sequential order, to achieve desirable results. It will be readily understood to those skilled in the art that various other changes in the details, materials, and arrangements of the parts and method stages which have been described and illustrated in order to explain the nature of this inventive subject matter may be made without departing from the principles and scope of the present disclosure.

1. A hinged mount assembly, comprising:
a clamp section having first and second clamp arms pivotally connected;
an adjustable arm section pivotally coupled to the clamp section; and
an attachment section coupled to the adjustable arm section, wherein the attachment section includes an attachment point for securing a device to the hinged mount assembly.

2. The hinged mount assembly of claim 1, wherein the adjustable arm section further comprises:
telescoping first and second tubing sections.

3. The hinged mount assembly of claim 2, wherein the first tubing section includes a series of adjustment holes along its length; and
the second tubing section includes a locking button configured to engage with the adjustment holes of the first tubing section to secure the relative positions of the first and second tubing sections.

4. The hinged mount assembly of claim 3, wherein the attachment section comprises a mounting hole for receiving a tent pole of an equipment cover.

5. The hinged mount assembly of claim 1, wherein the adjustable arm section further comprises:
a pivot sleeve pivotally coupled to the clamp section; and
a spring biasing the pivot sleeve against the clamp section to provide pivotal resistance.

6. The hinged mount assembly of claim 1, further comprising:
a yaw plate positioned between the adjustable arm section and the clamp section; and
wherein the yaw plate or the pivot sleeve comprise a textured surface for increasing the pivotal resistance.

7. The hinged mount assembly of claim 1, wherein the clamp section further comprises:
a threaded fastener connected to either the first or the second clamp arm; and
a thumb nut threadedly engaged with the threaded fastener for adjusting clamping force between the first and second clamp arms.

8. The hinged mount assembly of claim 1, further comprising clamp pads attached to inner surfaces of the first and second clamp arms.

9. The hinged mount assembly of claim 8, wherein the clamp pads have a textured surface for facilitating grip.

10. The hinged mount assembly of claim 1, wherein the attachment section comprises a mounting hole for receiving a tent pole of an equipment cover.

11. A portable equipment cover system, comprising:
a plurality of hinged mount assemblies, each hinged mount assembly comprising:
a clamp section having first and second clamp arms pivotally connected;
an adjustable arm section pivotally coupled to the clamp section; and
an attachment section coupled to the adjustable arm section, wherein the attachment section includes an attachment point for securing a device to the hinged mount assembly; and
a cover configured to be secured via the attachment sections of the hinged mount assemblies.

12. The system of claim 11, wherein the adjustable arm section further comprises:
telescoping first and second tubing sections.

13. The system of claim 12, wherein the first tubing section includes a series of adjustment holes along its length; and
the second tubing section includes a locking button configured to engage with the adjustment holes of the first tubing section to secure the relative positions of the first and second tubing sections.

14. The system of claim 13, wherein the attachment section comprises a mounting hole for receiving a tent pole of an equipment cover.

15. The system of claim 11, wherein the adjustable arm section further comprises:
a pivot sleeve pivotally coupled to the clamp section; and
a spring biasing the pivot sleeve against the clamp section to provide pivotal resistance.

16. The system of claim 11, further comprising:
a yaw plate positioned between the adjustable arm section and the clamp section,
wherein the yaw plate or the pivot sleeve comprise a textured surface for increasing the pivotal resistance.

17. The system of claim 11, wherein the clamp section further comprises:
a threaded fastener connected to either the first or the second clamp arm; and
a thumb nut threadedly engaged with the threaded fastener for adjusting clamping force between the first and second clamp arms.

18. The system of claim 11, further comprising clamp pads attached to inner surfaces of the first and second clamp arms.

19. The system of claim 18, wherein the clamp pads have a textured surface for facilitating grip.

20. The system of claim 11, wherein the attachment section comprises a mounting hole for receiving a tent pole of an equipment cover.
